(19) United States
(12) Patent Application Publication
(10) Pub. No.: US 2005/0084802 A1
(43) Pub. Date: Apr. 21, 2005

(54) Printing plate material

(75) Inventor: Takahiro Mori, Tokyo (JP)

Correspondence Address: MUSERLIAN, LUCAS AND MERCANTI, LLP, 475 PARK AVENUE SOUTH, 15TH FLOOR, NEW YORK, NY, 10016, US

(73) Assignee: Konica Minolta Medical & Graphic, Inc.

(21) Appl. No.: 10/960,320

(22) Filed: Oct. 7, 2004

(30) Foreign Application Priority Data
Oct. 17, 2003 (JP) JP2003-357647

(51) Int. Cl. G03F 7/26

(52) U.S. Cl. 430/300

(57) ABSTRACT

Disclosed is a printing plate material comprising a support and provided thereon, a light sensitive layer containing a sensitizing dye, which is insoluble in water and soluble in an organic solvent, and particles to which the sensitizing dye is adhered.

### FIELD OF THE INVENTION

The present invention relates to a printing plate material, and particularly to a printing plate material capable of forming an image by a computer to plate (CTP) system.

### BACKGROUND OF THE INVENTION

Recently, printing according to a CTP system has been carried out in printing industries, accompanied with the digitization of printing data. In this printing system, a planographic printing plate material for CTP, which is inexpensive, can be easily handled, and has a printing ability comparable with that of a PS plate, is required.

Recently, a versatile processless printing plate material, which can be applied to a printing press employing a direct imaging (DI) process without development by a special developing agent and which can be treated in the same manner as in PS plates, has been required.

In a thermal processless printing plate material, an image is formed according to a recording method employing an infrared laser emitting light with infrared to near infrared wavelengths. The thermal processless type printing plate material employing this recording method is divided into an ablation type printing plate material, and a development-on-press type heat fusible image formation layer-containing printing plate material.

Examples of the ablation type printing plate material include those disclosed in for example, Japanese Patent O.P.I. Publication Nos. 8-507727, 6-186750, 6-199064, 7-314934, 10-58636 and 10-244773. These references disclose a printing plate material comprising a substrate and a hydrophilic layer or a lipophilic layer, either of which is an outermost layer. In the printing plate material having a hydrophilic layer as an outermost layer, the hydrophilic layer is imagewise exposed to imagewise ablate the hydrophilic layer, whereby the lipophilic layer is exposed to form image portions. However, there is problem that contamination of the interior of the exposing apparatus by scattered matter caused by the ablation of the surface layer. This printing plate material requires a suction device in the exposing apparatus, and is low in versatility to the exposing apparatus.

The development-on-press type heat fusible image formation layer-containing printing plate material comprises a hydrophilic layer or a grained aluminum plate and provided thereon, an image formation layer containing thermoplastic particles, a water soluble binder, and a water soluble infrared absorbing dye (cyanine), as disclosed in Japanese Patent O.P.I. Publication No. 11-265062. This printing plate material does not cause ablation on exposure of appropriate exposure energy, which is high in versatility to the exposing apparatus.

The image formation layer of this printing plate material contains a water soluble dye. The dye is incorporated in a dampening solution during on-press development of the printing plate material on a printing press to color the dampening solution, and there is problem that the colored dampening solution contaminates the printing press. Further, there is problem that printing conditions change due to composition of the dampening solution (stain is likely to occur, or a balance of the dampening solution and the printing ink changes). Herein, provision of a dampening solution filtrating device is not effective, since the dye is water soluble.

Further, the dye is present in an image on the image formation layer formed by imagewise exposure, and is one of elements, which lowers water resistance of the image portions or printing durability.

An on-press development type printing plate material is disclosed in Japanese Patent O.P.I. Publication Nos. 2002-144750, which contains a water insoluble infrared dye having a specific functional group. This plate increases printing durability due to use of the water insoluble infrared dye. The image formation layer of the plate is provided on a hydrophilic support by coating the coating liquid containing an organic solvent as a main solvent on the support. The water insoluble dye is firmly adhered to the hydrophilic support surface and is difficult to remove on on-press development. As a result, the dye remaining on the hydrophilic support surface may produce stain at non-image portions of the printing plate.

There is a method disclosed in Japanese Patent O.P.I. Publication No. 2001-47754 which encapsulates an infrared absorbing dye into metal oxide particles, or a method disclosed in Japanese Patent O.P.I. Publication No. 2003-63164) which encapsulates an infrared absorbing dye into resin particles or microcapsules. These methods can prepare a printing plate material comprising a light sensitive layer containing a dye sparingly soluble in water which is easily on-press developed. In these methods, there is, however, problem in that the dye encapsulating process is complex, resulting in cost increase, or in that heating application in the course of the encapsulating process denatures the dye, resulting in lowering of light-to-heat conversion function.

There is a known method which obtains an aqueous dispersion of a cyanine dye having a water solubility by dispersing the dye in water (see for example, Japanese Patent O.P.I. Publication Nos. 8-220667, 8-245902 and 8-295821). There is, however, problem in this method in that since it is difficult to decrease an average particle diameter of the dye, light-to-heat conversion material function is poor relative to the dye content, resulting in lowering of sensitivity.

As described above, it has been difficult to provide a printing plate material of the on-press development type, giving high sensitivity, excellent on-press developability on a printing press and high printing durability.

### SUMMARY OF THE INVENTION

An object of the invention is to provide a printing plate material providing high sensitivity, excellent on-press developability, and high printing durability.

### DETAILED DESCRIPTION OF THE INVENTION

The above object of the invention can be attained by the following constitutions.

1. A printing plate material comprising a support and provided thereon, a light sensitive layer containing a sensitizing dye, which is insoluble in water and soluble in an organic solvent, and particles to which the sensitizing dye is adhered.

2. The printing plate material of item 1 above, wherein the sensitizing dye absorbs a light having a wavelength of from 700 to 1300 μm.

3. The printing plate material of item 1 above, further comprising a thermosensitive image formation layer provided on the support.

4. The printing plate material of item 3 above, wherein the thermosensitive image formation layer, after imagewise exposure, is capable of being developed with a dampening solution or a printing ink on printing.

5. The printing plate material of item 1 above, wherein the light sensitive layer is a thermosensitive image formation layer.

6. The printing plate material of item 1 above, wherein the particles are resin particles or microcapsules whose walls consist of a resin.

7. The printing plate material of item 6 above, wherein the resin particles are heat melting particles or heat fusible particles.

8. The printing plate material of item 1 above, wherein the light sensitive layer further contains a sensitizing dye in the form of particles.

9. A process of manufacturing a printing plate material comprising a support and provided thereon, a light sensitive layer containing a sensitizing dye, which is insoluble in water and soluble in an organic solvent, and particles to which the sensitizing dye is adhered, the process comprising the steps of:
mixing an aqueous dispersion of particles with an organic solvent solution of a sensitizing dye to obtain a light sensitive layer coating liquid; and
coating the light sensitive layer coating liquid on the support.

10. The process of item 9 above, wherein the organic solvent is miscible in water.

11. The process of item 10 above, wherein the organic solvent is alcohol.

12. The process of item 9 above, wherein the light sensitive layer coating liquid contains water in an amount of not less than 10% by weight.

1-1. A printing plate material comprising a hydrophilic support, and provided thereon, a light sensitive layer containing a sensitizing dye which is insoluble in water and soluble in an organic solvent, and particles on the surface of which the sensitizing dye is present.

1-2. The printing plate material of item 1-1 above, wherein the sensitizing dye absorbs a light having a wavelength of from 700 to 1300 μm.

1-3. The printing plate material of item 1-1 or 1-2 above, wherein a thermosensitive image formation layer is further provided on the support.

1-4. The printing plate material of item 1-3 above, wherein the thermosensitive image formation layer, after imagewise exposure, is capable of being developed with a dampening solution or a printing ink on printing.

1-5. The printing plate material of item 1-3 or 1-4 above, wherein the light sensitive layer is a thermosensitive image formation layer.

1-6. The printing plate material of any one of items 1-1 through 1-5 above, wherein the particles are resin particles or microcapsules whose walls consist of a resin.

1-7. The printing plate material of item 1-6 above, wherein the resin particles are heat melting particles or heat fusible particles.

1-8. The printing plate material of any one of items 1-1 through 1-7 above, wherein the particles are obtained by mixing an aqueous dispersion of particles with an organic solvent solution of the sensitizing dye.

1-9. The printing plate material of item 1-8 above, wherein the organic solvent is miscible in water.

1-10. The printing plate material of item 1-9 above, wherein the organic solvent is alcohol.

1-11. The printing plate material of any one of items 1-1 through 1-10 above, wherein the light sensitive layer further contains a sensitizing dye in the form of particles.

1-12. The printing plate material of any one of items 1-1 through 1-11 above, wherein the light sensitive layer is obtained by coating on the support a light sensitive layer coating liquid containing water in an amount of not less than 10% by weight.

The printing plate material of the invention comprises a light sensitive layer containing a sensitizing dye which is insoluble in water and soluble in an organic solvent (hereinafter also referred to as the sensitizing dye in the invention), and particles on the surface of which the sensitizing dye is present.

In the invention, the sensitizing dye which is insoluble in water and soluble in an organic solvent is a sensitizing dye having a solubility in 25° C. water of less than 0.1% by weight, and having a solubility in 25° C. ethanol of not less than 0.1% by weight. In the invention, a sensitizing dye having a solubility in 25° C. water of not more than 0.00001% by weight is preferably used.

The light sensitive layer in the invention contains the sensitizing dye in the invention in an amount of preferably from 0.1 to 20% by weight, and more preferably from 0.5 to 10% by weight.

The sensitizing dye is preferably a dye absorbing an infrared to near-infrared light, typically, a dye absorbing a light with wavelength regions of from 700 to 1300 μm and generating heat (the sensitizing dye also serves as a light-to-heat conversion material).

Examples of such a dye include a general infrared absorbing dye such as a cyanine dye, a chloconium dye, a polymethine dye, an azulenium dye, a squalenium dye, a thiopyrylium dye, a naphthoquinone dye or an anthraquinone dye, and an organometallic complex such as a phthalocyanine compound, a naphthalocyanine compound, an azo compound, a thioamide compound, a dithiol compound or an indoaniline compound. Of these, a cyanine dye is especially preferred.

Exemplified compounds of the cyanine dye will be listed below, but the invention is not limited thereto.

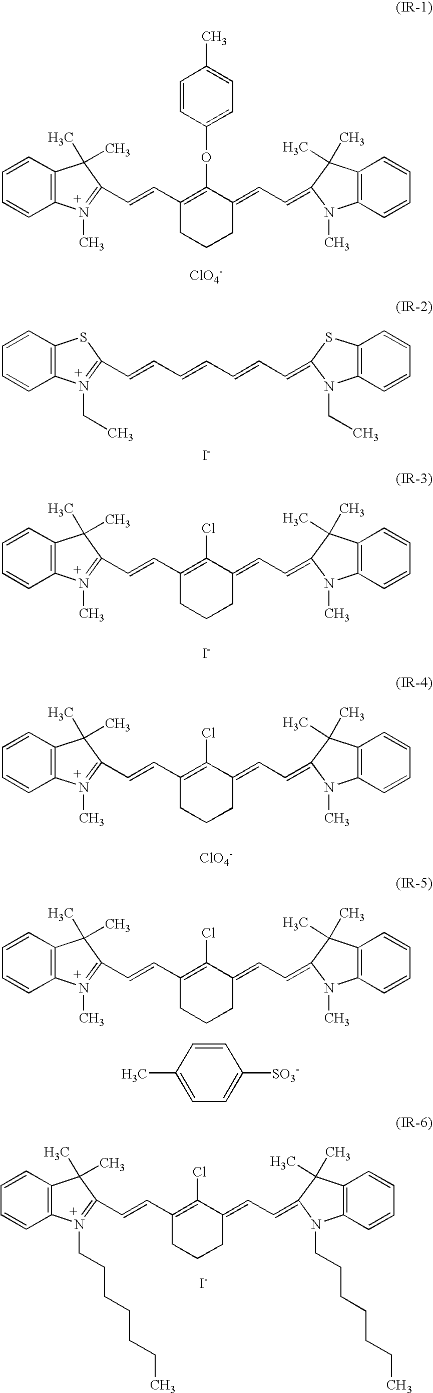

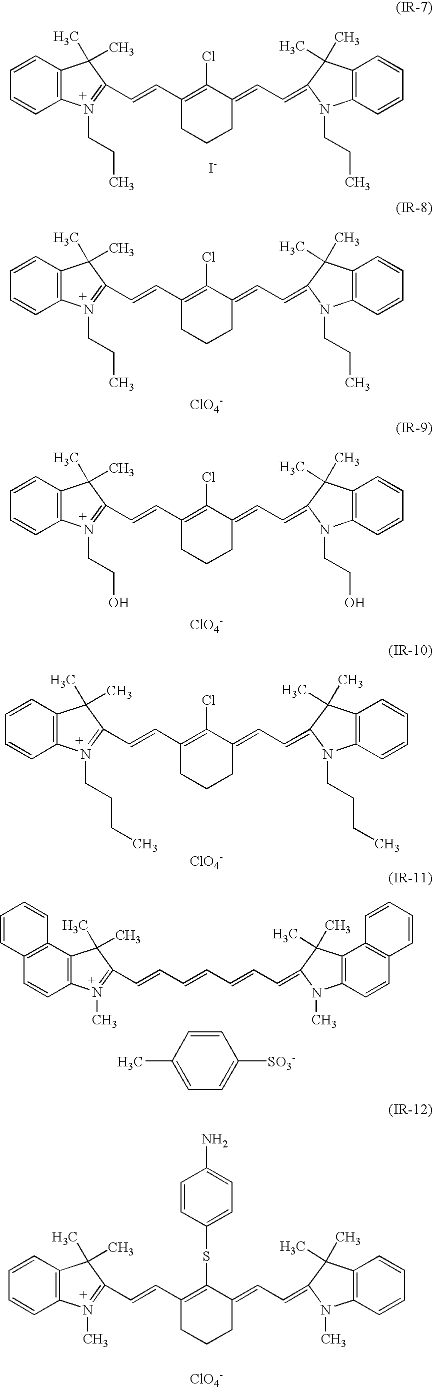

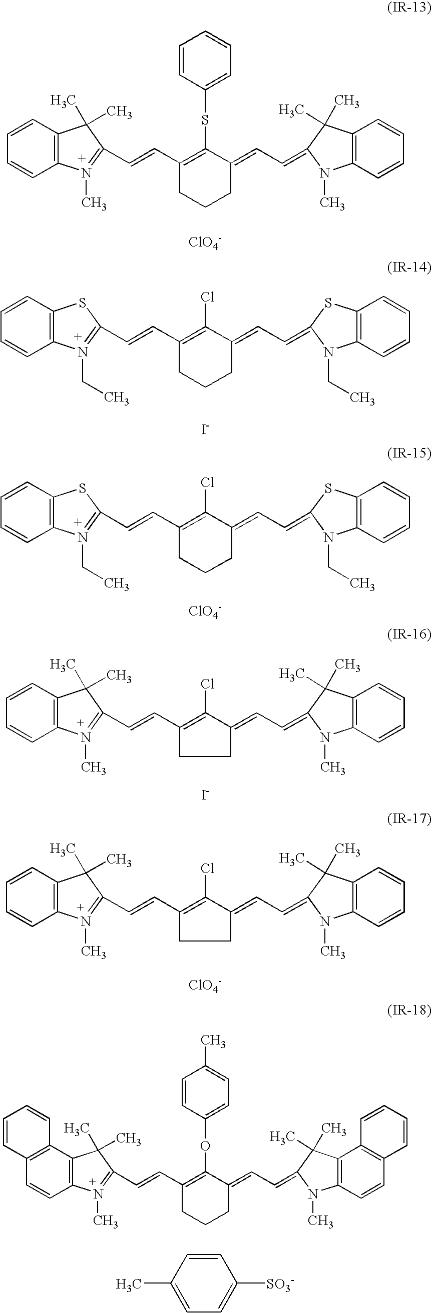

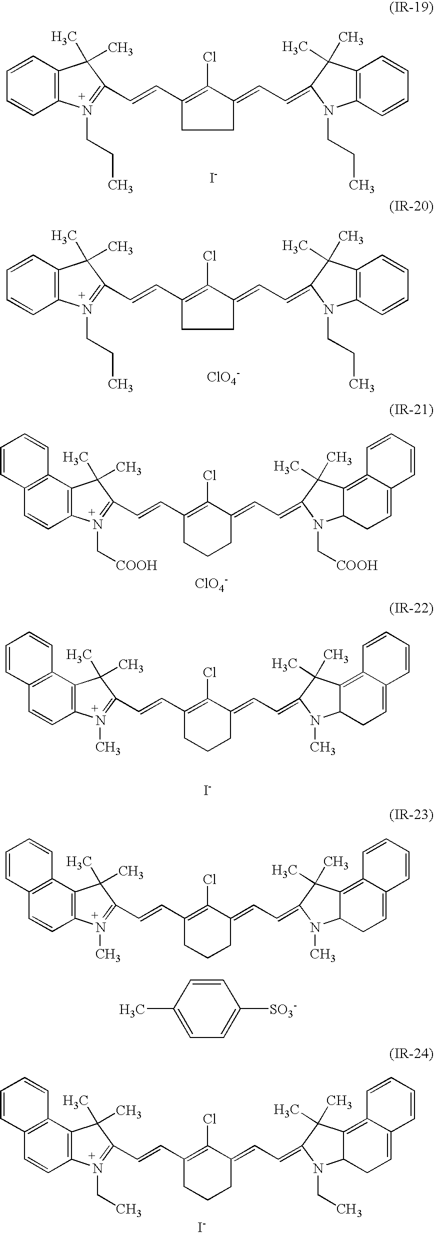

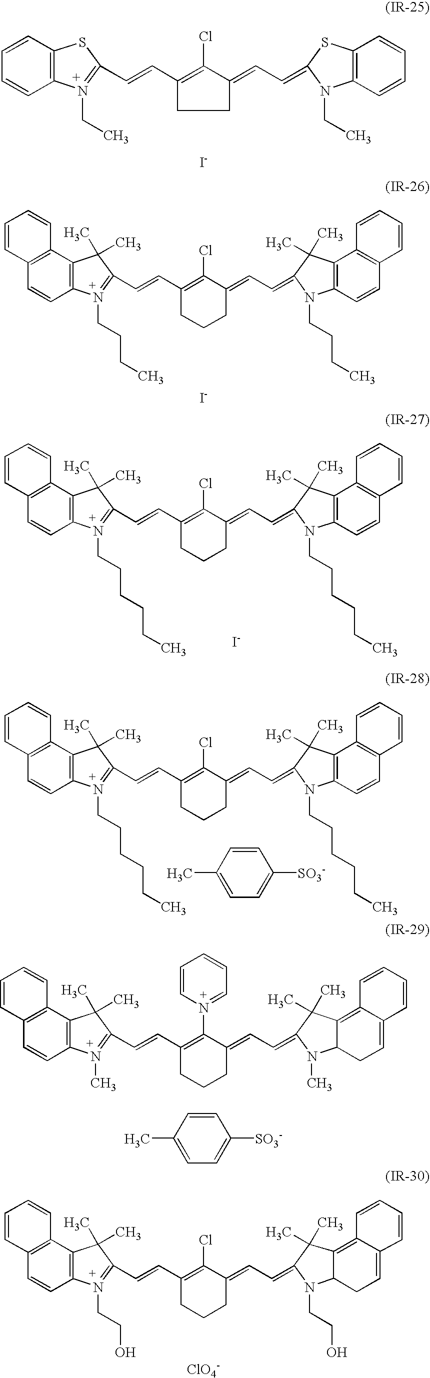

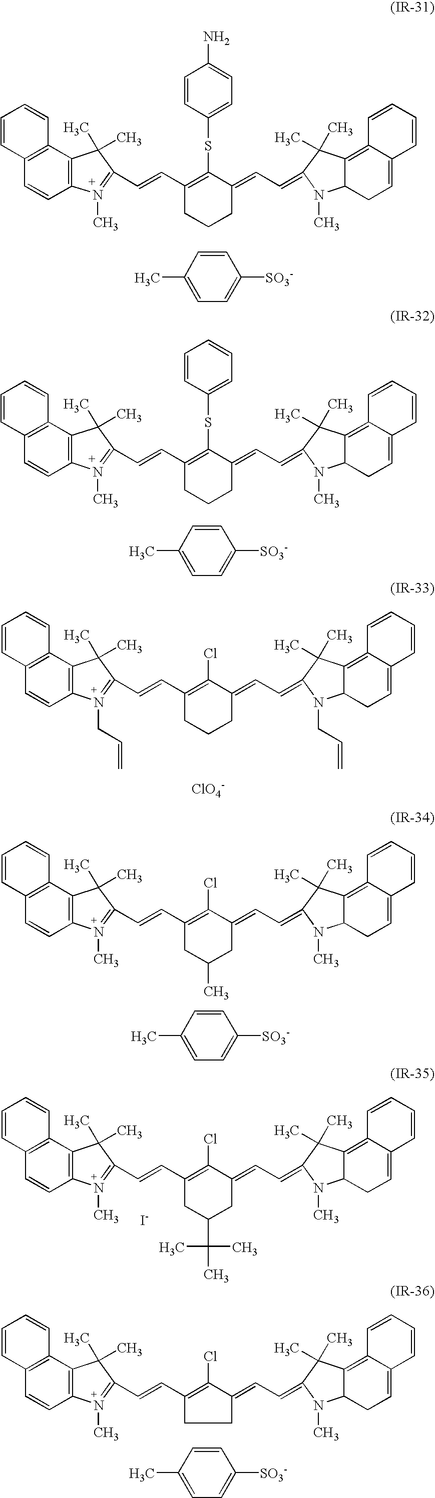

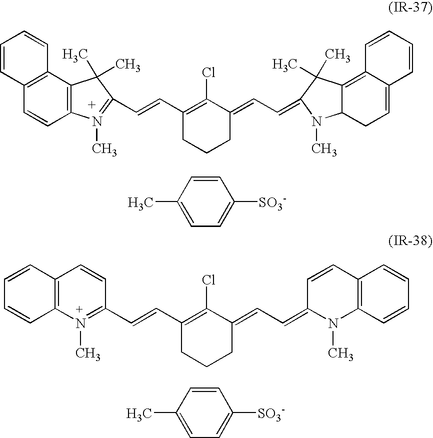

The printing plate material of the invention preferably comprises a thermosensitive image formation layer. That is, a printing plate material, comprising a light sensitive layer containing the dye described above and a thermosensitive image formation layer exhibits the effects of the invention more markedly. It is especially preferred in the invention that the light sensitive layer is the thermosensitive image formation layer.

The thermosensitive image formation layer preferably contains heat-melting particles or heat-fusible particles.

In the invention, the particles, to which the sensitizing dye is adhered, have a particle diameter of not more than 10 μm. The shape of the particles may be porous or hollow.

Herein, “particle diameter” implies a diameter of a circle having the largest area among circles having the same area as the projected area of the particles.

The particles in the invention have an average particle diameter of preferably from 0.01 to 10 μm, and more preferably from 0.03 to 3 μm.

The average particle diameter of the particles is measured according to the following means. The average particle diameter is a peak value of a particle size distribution curve measured employing a laser diffraction/scatter particle size distribution measuring device (for example, LA-300 produced by HORIBA Co., Ltd.).

The content of the particles in the light sensitive layer is preferably from 5 to 99.9% by weight, more preferably from 20 to 95% by weight, and most preferably from 40 to 90% by weight.

As the particles in the invention, particles of an organic compound, an inorganic compound, and their composite can be used. The particles are preferably resin particles consisting of a resin or microcapsules having walls consisting of a resin. The resin particles are preferably heat-melting or heat-fusible, and more preferably the heat-melting particles or heat-fusible particles described above contained in the thermosensitive image formation layer.

The heat melting particles are particularly particles having a low melt viscosity, which are particles formed from materials generally classified into wax. The materials preferably have a softening point of from 40° C. to 120° C. and a melting point of from 60° C. to 150° C., and more preferably a softening point of from 40° C. to 10° C. and a melting point of from 60° C. to 120° C.

Materials usable include waxes such as paraffin wax, polyolefin wax (for example, polyethylene wax), microcrystalline wax, and fatty acid and its ester derivatives. The molecular weight thereof is approximately from 800 to 10,000. A polar group such as a hydroxyl group, an ester group, a carboxyl group, an aldehyde group and a peroxide group may be introduced into the wax by oxidation to increase the emulsification ability.

Moreover, stearoamide, linolenamide, laurylamide, myristylamide, hardened cattle fatty acid amide, parmitylamide, oleylamide, rice bran oil fatty acid amide, palm oil fatty acid amide, a methylol compound of the above-mentioned amide compounds, methylenebissteastearoamide and ethylenebissteastearoamide may be added to the wax in order to lower the softening point or to raise the working efficiency. A cumarone-indene resin, a rosin-modified phenol resin, a terpene-modified phenol resin, a xylene resin, a ketone resin, an acryl resin, an ionomer and a copolymer of these resins may also be usable.

Among them, polyethylene wax, microcrystalline wax, fatty acid ester or fatty acid is preferably contained. These materials are preferred in increasing sensitivity.

The composition of the heat melting particles may-be continuously varied from the interior to the surface of the particles. The particles may be covered with a different material. Known microcapsule production method or sol-gel method can be applied for covering the particles.

The heat fusible particles include thermoplastic hydrophobic polymer particles. Although there is no specific limitation to the upper limit of the softening point of the thermoplastic hydrophobic polymer, the softening point is preferably lower than the decomposition temperature of the polymer. The weight average molecular weight (Mw) of the thermoplastic hydrophobic polymer is preferably within the range of from 10,000 to 1,000,000.

Examples of the polymer consisting the polymer particles include a diene (co)polymer such as polypropylene, polybutadiene, polyisoprene or an ethylene-butadiene copolymer; a synthetic rubber such as a styrene-butadiene copolymer, a methyl methacrylate-butadiene copolymer or an acrylonitrile-butadiene copolymer; a (meth)acrylate (co)polymer or a (meth)acrylic acid (co)polymer such as polymethyl methacrylate, a methyl methacrylate-(2-ethylhexyl)acrylate copolymer, a methyl methacrylate-methacrylic acid copolymer, or a methyl acrylate-(N-methylolacrylamide); polyacrylonitrile; a vinyl ester (co)polymer such as a polyvinyl acetate, a vinyl acetate-vinyl propionate copolymer and a vinyl acetate-ethylene copolymer, or a vinyl acetate-2-hexylethyl acrylate copolymer; and polyvinyl chloride, polyvinylidene chloride, polystyrene and a copolymer thereof. Among them, the (meth)acrylate polymer, the (meth)acrylic acid (co)polymer, the vinyl ester (co)polymer, the polystyrene and the synthetic rubbers are preferably used.

The polymer particles may be prepared from a polymer synthesized by any known method such as an emulsion polymerization method, a suspension polymerization method, a solution polymerization method and a gas phase polymerization method. The particles of the polymer synthesized by the solution polymerization method or the gas phase polymerization method can be produced by a method in which an organic solution of the polymer is sprayed into an inactive gas and dried, and a method in which the polymer is dissolved in a water-immiscible solvent, then the resulting solution is dispersed in water or an aqueous medium and the solvent is removed by distillation. In both of the methods, a surfactant such as sodium lauryl sulfate, sodium dodecylbenzenesulfate or polyethylene glycol, or a water-soluble resin such as poly(vinyl alcohol) may be optionally used as a dispersing agent or stabilizing agent.

Further, the composition of the heat fusible particles may be continuously varied from the interior to the surface of the particles. The particles may be covered with a different material. As a covering method, known methods such as a microcapsule method and a sol-gel method are usable. The heat fusible particle content of the layer is preferably from 1 to 90% by weight, and more preferably from 5 to 80% by weight based on the total weight of the layer.

The average particle diameter of the heat melting particles or the heat-fusible particles is preferably from 0.01 to 10 μm, and more preferably from 0.1 to 3 μm, in view of sensitivity, on-press developability and dissolving power.

Microcapsules whose walls consist of a resin include microcapsules encapsulating oleophilic materials disclosed in Japanese Patent O.P.I. Publication Nos. 2002-2135 and 2002-19317.

As the resins for the microcapsule walls, known materials can be used. As a method of manufacturing the microcapsules, known methods can be used. The resins for the microcapsule walls and the manufacturing method of the microcapsule wall can be applied which are disclosed in for example, Tamotsu Kondo, Masumi Koishi, “New Edition Microcapsule, Its Manufacturing Method, Properties And Application”, published by Sankyo Shuppan Co., Ltd., or disclosed in literatures cited in it.

The average microcapsule diameter of the microcapsules is preferably from 0.1 to 10 μm, more preferably from 0.3 to 5 μm, and still more preferably from 0.5 to 3 μm. The thickness of the microcapsule wall is preferably from 1/100 to ⅕ of the average microcapsule diameter, and more preferably from 1/50 to 1/10 of the average microcapsule diameter. The microcapsule content of the image formation layer is preferably from 5 to 100% by weight, more preferably from 20 to 95% by weight, and most preferably from 40 to 90% by weight.

In the invention, a method of adhering a sensitizing dye onto the surface of the particles comprises mixing an aqueous dispersion of the particles with an organic solvent solution of the sensitizing dye. It is preferred that the organic solvent solution of the sensitizing dye is dropwise added to the aqueous dispersion of the particles.

The organic solvent used in the invention is preferably an organic solvent miscible in water, and is more preferably alcohols such as methanol, ethanol, and isopropanol. Ethanol is especially preferred in solubility or safety. Herein, “an organic solvent miscible in water” implies an organic solvent having a solubility in 25° C. water of not less than 100% by weight.

The aqueous dispersion of the particles is obtained by dispersing in water an organic compound, an inorganic compound, or an organic-inorganic composite according to known methods. The dispersion method is not specifically limited, there is, for example, a dispersion method employing a known dispersant, or a dispersion method providing self-dispersibility to the particles. Dispersion is preferred which can maintain good dispersion stability even when the aqueous dispersion is mixed with an organic solvent.

The light sensitive layer is provided on a support by coating a coating liquid comprising the aqueous dispersion described above on the support and drying. The coating liquid for the light sensitive layer contains water in an amount of preferably not less than 10% by weight, more preferably not less than 30% by weight, and still more preferably not less than 50% by weight.

It is preferred in the invention that the light sensitive layer further contains the sensitizing dye in the form of particles (hereinafter also referred to as the sensitizing dye particles). As a method to prepare the sensitizing dye in the form of particles, there is, for example, a method, in which a dispersion of the sensitizing dye particles is prepared separately and mixed with the coating liquid for the light sensitive layer; or a method which produces the sensitizing dye particles at the same time when the sensitizing dye-adhered particles are prepared as described above.

The average particle diameter of the sensitizing dye particles is preferably from 0.01 to 1 μm, and more preferably from 0.01 to 0.2 μm.

[Support]

The support in the invention is a plate or a film sheet capable of carrying a component layer such as a hydrophilic layer or an image formation layer, and those well known in the art as supports for printing plates can be used.

Examples of the support include a metal plate, a plastic film sheet, a paper sheet treated with polyolefin, and composite materials such as laminates thereof. The thickness of the support is not specifically limited as long as a printing plate having the support can be mounted on a printing press, and is advantageously from 50 to 500 μm in easily handling.

Examples of metals of the metal plate for the support include iron, stainless steel, and aluminum. Aluminum is especially preferable in its gravity and stiffness. An aluminum plate is ordinarily used after degreased with an alkali, an acid or a solvent to remove oil on the surface, which has been used when rolled and wound around a spool.

The degreasing is carried out preferably employing an aqueous alkali solution. In order to increase adhesion between the support and a coating layer, it is preferred that the surface of the support is subjected to adhesion increasing treatment or is coated with a subbing layer. For example, the support is immersed in a solution containing silicate or a coupling agent such as a silane coupling agent, or the support is coated with the solution and then sufficiently dried. Anodization treatment is considered to be one kind of adhesion increasing treatment, and can be used. The anodization treatment and the immersing or coating treatment described above can be used in combination. An aluminum plate (so-called grained aluminum plate), which has been surface-roughened with a conventional method, can be used as a support having a hydrophilic surface.

Examples of the plastic film include a polyethylene terephthalate film, a polyethylene naphthalate film, a polyimide film, a polyamide film, a polycarbonate film, a polysulfone film, a polyphenylene oxide film, and a cellulose ester film.

The plastic film is preferably a polyethylene terephthalate film, or a polyethylene naphthalate film. In order to increase adhesion between the support and a coating layer, it is preferred that the surface of the plastic film is subjected to adhesion increasing treatment or is coated with a subbing layer. Examples of the adhesion increasing treatment include corona discharge treatment, flame treatment, plasma treatment and UV light irradiation treatment. Examples of the subbing layer include a layer containing gelatin or latex. The subbing layer can contain known organic or inorganic electrically conductive material.

A support can be preferably used which is provided with a known back coat layer for the purpose of controlling slipping property of the back coat layer (for example, reducing a coefficient of friction between the back coat layer and the surface of the plate cylinder of a press) or controlling the electroconductivity.

[Hydrophilic Layer]

The hydrophilic layer in the invention is a layer capable of forming non-image portions repelling printing ink on printing, or is for example, a hydrophilic layer provided on a support or a surface layer of a support itself whose surface has been subjected to hydrophilization treatment.

The hydrophilic layer may be a single layer or plural layers. The coating amount of the hydrophilic layer is preferably from 0.1 to 10 g/m², and more preferably from 0.2 to 5 g/m². Hydrophilic materials used in the hydrophilic layer are preferably materials, which are hydrophilic and substantially insoluble in water, and more preferably metal oxides.

The metal oxides are preferably metal oxide particles. Examples of the metal oxide particles include colloidal silica particles, an alumina sol, a titania sol and another metal oxide sol. The metal oxide particles may have any shape such as spherical, needle-like, and feather-like shape. The average particle diameter is preferably from 3 to 100 nm, and plural kinds of metal oxide each having a different diameter may be used in combination. The surface of the particles may be subjected to surface treatment.

The metal oxide particles can be used as a binder, utilizing its layer forming ability. The metal oxide particles are suitably used in a hydrophilic layer since they minimize lowering of the hydrophilicity of the layer as compared with an organic compound binder.

Among the above-mentioned, colloidal silica is particularly preferred. The colloidal silica has a high layer forming ability under a drying condition with a relative low temperature, and can provide a good layer strength even in a layer containing not less than 91% by weight of a material containing no carbon atom.

It is preferred that the colloidal silica used in the invention is necklace-shaped colloidal silica or colloidal silica particles having an average particle diameter of not more than 20 nm, each being described later. Further, it is preferred that the colloidal silica provides an alkaline colloidal silica solution as a colloid solution.

The necklace-shaped colloidal silica to be used in the invention is a generic term of an aqueous dispersion system of spherical silica having a primary particle size of the order of nm. The necklace-shaped colloidal silica to be used in the invention means a “pearl necklace-shaped” colloidal silica formed by connecting spherical colloidal silica particles each having a primary particle size of from 10 to 50 μm so as to attain a length of from 50 to 400 nm. The term of “pearl necklace-shaped” means that the image of connected colloidal silica particles is like to the shape of a pearl necklace. The bonding between the silica particles forming the necklace-shaped colloidal silica is considered to be —Si—O—Si—, which is formed by dehydration of —SiOH groups located on the surface of the silica particles. Concrete examples of the necklace-shaped colloidal silica include Snowtex-PS series produced by Nissan Kagaku Kogyo, Co., Ltd.

Concrete examples of the necklace-shaped colloidal silica include Snowtex-PS series produced by Nissan Kagaku Kogyo, Co., Ltd. As the products, there are Snowtex-PS—S (the average particle diameter in the connected state is approximately 110 nm), Snowtex-PS-M (the average particle diameter in the connected state is approximately 120 nm) and Snowtex-PS-L (the average particle diameter in the connected state is approximately 170 nm). Acidic colloidal silicas corresponding to each of the above-mentioned are Snowtex-PS-S-O, Snowtex-PS-M-O and Snowtex-PS-L-O, respectively.

The necklace-shaped colloidal silica can maintain layer strength, securing porosity of a layer, and can be used as a material providing porosity of layer.

Among them, the use of Snowtex-PS-S, Snowtex-PS-M or Snowtex-PS-L, each being alkaline colloidal silica particles, is particularly preferable since the strength of the hydrophilic layer is increased and occurrence of background contamination is inhibited even when a lot of prints are printed.

It is known that the binding force of the colloidal silica particles is become larger with decrease of the particle diameter. The average particle diameter of the colloidal silica particles to be used in the invention is preferably not more than 20 nm, and more preferably 3 to 15 nm. Alkaline colloidal silica particles of colloidal silica particles show the effect of inhibiting occurrence of the background contamination. Accordingly, the use of the alkaline colloidal silica particles is particularly preferable. Examples of the alkaline colloidal silica particles having the average particle diameter within the foregoing range include Snowtex-20 (average particle diameter: 10 to 20 nm), Snowtex-30 (average particle diameter: 10 to 20 nm), Snowtex-40 (average particle diameter: 10 to 20 nm), Snowtex-N (average particle diameter: 10 to 20 nm), Snowtex-S (average particle diameter: 8 to 11 nm) and Snowtex-XS (average particle diameter: 4 to 6 nm), each produced by Nissan Kagaku Co., Ltd.

The hydrophilic layer in the invention can contain necklace-shaped colloidal silica as a porosity providing material.

The colloidal silica particles having an average particle diameter of not more than 20 nm, when used together with the necklace-shaped colloidal silica as described above, is particularly preferred, since appropriate porosity of the layer is maintained and the layer strength is further increased.

The ratio of the colloidal silica particles having an average particle diameter of not more than 20 nm to the necklace-shaped colloidal silica is preferably from 95/5 to 5/95, more preferably from 70/30 to 20/80, and most preferably from 60/40 to 30/70.

The hydrophilic layer in the invention preferably contains porous metal oxide particles as metal oxide particles. Examples of the porous metal oxide particles include porous silica particles, porous aluminosilicate particles or zeolite particles as described later.

The porous silica particles are ordinarily produced by a wet method or a dry method. By the wet method, the porous silica particles can be obtained by drying and pulverizing a gel prepared by neutralizing an aqueous silicate solution, or pulverizing the precipitate formed by neutralization. By the dry method, the porous silica particles are prepared by combustion of silicon tetrachloride together with hydrogen and oxygen to precipitate silica. The porosity and the particle diameter of such particles can be controlled by variation of the production conditions. The porous silica particles prepared from the gel by the wet method is particularly preferred.

The porous aluminosilicate particles can be prepared by the method described in, for example, JP O.P.I. No. 10-71764. Thus prepared aluminosilicate particles are amorphous complex particles synthesized by hydrolysis of aluminum alkoxide and silicon alkoxide as the major components. The particles can be synthesized so that the ratio of alumina to silica in the particles is within the range of from 1:4 to 4:1. Complex particles composed of three or more components prepared by an addition of another metal alkoxide may also be used in the invention. In such a particle, the porosity and the particle diameter can be controlled by adjustment of the production conditions.

The porosity of the particles is preferably not less than 1.0 ml/g, more preferably not less than 1.2 ml/g, and most preferably of from 1.8 to 2.5 ml/g, in terms of pore volume before the dispersion.

The particle diameter of the particles dispersed in the hydrophilic layer (or in the dispersed state before formed as a layer) is preferably not more than 1 μm, and more preferably not more than 0.5 μm.

The hydrophilic layer of the printing plate material in the invention can contain layer structural clay mineral particles as a metal oxide. Examples of the layer structural clay mineral particles include a clay mineral such as kaolinite, halloysite, talk, smectite such as montmorillonite, beidellite, hectorite and saponite, vermiculite, mica and chlorite; hydrotalcite; and a layer structural polysilicate such as kanemite, makatite, ilerite, magadiite and kenyte. Among them, ones having a higher electric charge density of the unit layer are higher in the polarity and in the hydrophilicity. Preferable charge density is not less than 0.25, more preferably not less than 0.6. Examples of the layer structural mineral particles having such a charge density include smectite having a negative charge density of from 0.25 to 0.6 and bermiculite having a negative charge density of from 0.6 to 0.9. Synthesized fluorinated mica is preferable since one having a stable quality, such as the particle diameter, is available. Among the synthesized fluorinated mica, swellable one is preferable and one freely swellable is more preferable.

An intercalation compound of the foregoing layer structural mineral particles such as a pillared crystal, or one treated by an ion exchange treatment or a surface treatment such as a silane coupling treatment or a complication treatment with an organic binder is also usable.

The planar structural mineral particles are preferably in the plate form, and have an average particle diameter (an average of the largest particle length) of preferably not more than 20 μm, and an average aspect ratio (the largest particle length/the particle thickness) of preferably not less than 20, and more preferably not less than 50, in a state contained in the layer including the case that the particles are subjected to a swelling process and a dispersing layer-separation process. The particles more preferably have an average particle diameter of preferably not more than 5 μm, and an average aspect ratio of not less than 50, and still more preferably have an average particle diameter of preferably not more than 1 μm, and an average aspect ratio of not less than 50. When the particle diameter is within the foregoing range, continuity to the parallel direction, which is a trait of the layer structural particle, and softness, are given to the coated layer so that a strong dry-layer in which a crack is difficult to be formed can be obtained. The coating solution containing the layer structural clay mineral particles in a large amount can minimize particle sedimentation due to a viscosity increasing effect.

The content of the layer structural clay mineral particles is preferably from 0.1 to 30% by weight, and more preferably from 1 to 10% by weight based on the total weight of the layer. Particularly, the addition of the swellable synthesized fluorinated mica or smectite is effective if the adding amount is small. The layer structural clay mineral particles may be added in the form of powder to a coating liquid, but it is preferred that gel of the particles which is obtained by being swelled in water, is added to the coating liquid in order to obtain a good dispersity according to an easy coating liquid preparation method which requires no dispersion process comprising dispersion due to media.

An aqueous solution of a silicate is also usable as another additive to the hydrophilic matrix phase in the invention. An alkali metal silicate such as sodium silicate, potassium silicate or lithium silicate is preferable, and the SiO₂/M₂O is preferably selected so that the pH value of the coating liquid after addition of the silicate does not exceed 13 in order to prevent dissolution of the porous metal oxide particles or the colloidal silica particles.

An inorganic polymer or an inorganic-organic hybrid polymer prepared by a sol-gel method employing a metal alkoxide. Known methods described in S. Sakka “Application of Sol-Gel Method” or in the publications cited in the above publication can be applied to prepare the inorganic polymer or the inorganic-organic hybridpolymer by the sol-gel method.

In the invention, the hydrophilic layer may contain a hydrophilic organic resin. Examples thereof include polysaccharides, polyethylene oxide, polypropylene oxide, polyvinyl alcohol, polyethylene glycol (PEG), polyvinyl ether, a styrene-butadiene copolymer, a conjugation diene polymer latex of methyl methacrylate-butadiene copolymer, an acryl polymer latex, a vinyl polymer latex, polyacrylamide, and polyvinyl pyrrolidone.

A cationic resin may also be contained in the hydrophilic layer. Examples of the cationic resin include a polyalkylene-polyamine such as a polyethyleneamine or polypropylenepolyamine or its derivative, an acryl resin having a tertiary amino group or a quaternary ammonium group and diacrylamine. The cationic resin may be added in a form of fine particles. Examples of such particles include the cationic microgel described in Japanese Patent O.P.I. Publication No. 6-161101.

In the invention, it is preferred that the hydrophilic organic resin contained in the hydrophilic layer is a water soluble resin, and at least a part of the resin exists in the hydrophilic layer in a state capable of being dissolved in water.

The water soluble material contained in the hydrophilic layer in the invention is preferably a saccharide.

As the saccharides, oligosaccharide detailed later can be used, but polysaccharides are preferably used.

As the polysaccharide, starches, celluloses, polyuronic acid and pullulan can be used. Among them, a cellulose derivative such as a methyl cellulose salt, a carboxymethyl cellulose salt or a hydroxyethyl cellulose salt is preferable, and a sodium or ammonium salt of carboxymethyl cellulose is more preferable. These polysaccharides can form a preferred surface shape of the hydrophilic layer.

The surface of the hydrophilic layer preferably has a convexoconcave structure having a pitch of from 0.1 to 50 μm such as the grained aluminum surface of an aluminum PS plate. The water retention ability and the image maintaining ability are raised by such a convexoconcave structure of the surface. Such a convexoconcave structure can also be formed by adding in an appropriate amount a filler having a suitable particle size to the coating liquid of the hydrophilic layer. However, the convexoconcave structure is preferably formed by coating a coating liquid for the hydrophilic layer containing the alkaline colloidal silica and the water-soluble polysaccharide so that the phase separation occurs at the time of drying the coated liquid, whereby a structure is obtained which provides a good printing performance.

The shape of the convexoconcave structure such as the pitch and the surface roughness thereof can be suitably controlled by the kinds and the adding amount of the alkaline colloidal silica particles, the kinds and the adding amount of the water-soluble polysaccharide, the kinds and the adding amount of another additive, a solid concentration of the coating liquid, a wet layer thickness or a drying condition.

The pitch in the convexoconcave structure is preferably from 0.2 to 30 μm, and more preferably from 0.5 to 20 μm. A multi-layered convexoconcave structure may be formed in which a convexoconcave structure with a smaller pitch is formed on one with a larger pitch. The hydrophilic layer has a surface roughness Ra of preferably from 100 to 1000 nm, and more preferably from 150 to 600 nm.

The thickness of the hydrophilic layer is from 0.01 to 50 μm, preferably from 0.2 to 10 μm, and more preferably from 0.5 to 3 μm.

A water-soluble surfactant may be added for improving the coating ability of the coating liquid for the hydrophilic layer in the invention. A silicon atom-containing surfactant and a fluorine atom-containing surfactant are preferably used. The silicon atom-containing surfactant is especially preferred in that it minimizes printing contamination. The content of the surfactant is preferably from 0.01 to 3% by weight, and more preferably from 0.03 to 1% by weight based on the total weight of the hydrophilic layer (or the solid content of the coating liquid).

The hydrophilic layer in the invention can contain a phosphate. Since a coating liquid for the hydrophilic layer is preferably alkaline, the phosphate to be added to the hydrophilic layer is preferably sodium phosphate or sodium monohydrogen phosphate. The addition of the phosphate provides improved reproduction of dots at shadow portions. The content of the phosphate is preferably from 0.1 to 5% by weight, and more preferably from 0.5 to 2% by weight in terms of amount excluding hydrated water.

The preferred hydrophilic support is an aluminum plate whose surface has been subjected to hydrophilization treatment, and cab be obtained by surface-roughening the aluminum plate.

It is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support. The surface roughening methods include a mechanical surface roughening method and an electrolytic surface roughening method electrolytically etching the support surface.

Though there is no restriction for the mechanical surface roughening method, a brushing roughening method and a honing roughening method are preferable.

Though there is no restriction for the electrolytic surface roughening method, a method, in which the support is electrolytically surface roughened in an acidic electrolytic solution, is preferred.

After the support has been electrolytically surface roughened, it is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the surface of the support.

The support which has been subjected to anodizing treatment is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the support is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in Japanese Patent O.P.I. Publication No. 5-304358, which has a functional group capable of causing addition reaction by radicals as a covalent bond, is suitably used.

The hydrophilic layer or image formation layer can optionally contain a light-to-heat conversion material.

As the light-to-heat conversion material, there are the sensitizing dye described above, which also serves a light-to-heat conversion material, and pigment.

Examples of the sensitizing dye include a general infrared absorbing dye such as a cyanine dye, a chloconium dye, a polymethine dye, an azulenium dye, a squalenium dye, a thiopyrylium dye, a naphthoquinbne dye or an anthraquinone dye, and an organometallic complex such as a phthalocyanine compound, a naphthalocyanine compound, an azo compound, a thioamide compound, a dithiol compound or an indoaniline compound. Exemplarily, the light-to-heat conversion materials include compounds disclosed in Japanese Patent O.P.I. Publication Nos. 63-139191, 64-33547, 1-160683, 1-280750, 1-293342, 2-2074, 3-26593, 3-30991, 3-34891, 3-36093, 3-36094, 3-36095, 3-42281, 3-97589 and 3-103476. These compounds may be used singly or in combination.

Compounds described in Japanese Patent O.P.I. Publication Nos. 11-240270, 11-265062, 2000-309174, 2002-49147, 2001-162965, 2002-144750, and 2001-219667 can be preferably used.

Examples of pigment include carbon, graphite, a metal and a metal oxide. Furnace black and acetylene black is preferably used as the carbon. The graininess (d₅₀) thereof is preferably not more than 100 nm, and more preferably not more than 50 nm.

The graphite is one having a particle size of preferably not more than 0.5 μm, more preferably not more than 100 nm, and most preferably not more than 50 nm.

As the metal, any metal can be used as long as the metal is in a form of fine particles having preferably a particle size of not more than 0.5 μm, more preferably not more than 100 nm, and most preferably not more than 50 nm. The metal may have any shape such as spherical, flaky and needle-like. Colloidal metal particles such as those of silver or gold are particularly preferred.

As the metal oxide, materials having black color in the visible regions or materials, which are electro-conductive or semiconductive can be used. Examples of the former include black iron oxide and black complex metal oxides containing at least two metals. Examples of the latter include Sb-doped SnO₂ (ATO), Sn-added In₂O₃ (ITO), TiO₂, TiO prepared by reducing TiO₂ (titanium oxide nitride, generally titanium black). Particles prepared by covering a core material such as BaSO₄, TiO₂, 9 Al₂O₃.2B₂O and K₂O.nTiO₂ with these metal oxides is usable. These oxides are particles having a particle size of not more than 0.5 μm, preferably not more than 100 nm, and more preferably not more than 50 nm.

As these light-to-heat conversion materials, black iron oxide or black complex metal oxides containing at least two metals are more preferred.

The black iron oxide (Fe₃O₄) particles have an average particle diameter of from 0.01 to 1 μm, and an acicular ratio (major axis length/minor axis length) of preferably from 1 to 1.5. It is preferred that the black iron oxide particles are substantially spherical ones (having an acicular ratio of 1) or octahedral ones (having an acicular ratio of 1.4).

Examples of the black iron oxide particles include for example, TAROX series produced by Titan Kogyo K.K. Examples of the spherical particles include BL-100 (having a particle diameter of from 0.2 to 0.6 μm, and BL-500 (having a particle diameter of from 0.3 to 1.0 μm. Examples of the octahedral particles include ABL-203 (having a particle diameter of from 0.4 to 0.5 μm, ABL-204 (having a particle diameter of from 0.3 to 0.4 μm, ABL-205 (having a particle diameter of from 0.2 to 0.3 μm, and ABL-207 (having a particle diameter of 0.2 μm.

The black iron oxide particles may be surface-coated with inorganic compounds such as SiO₂. Examples of such black iron oxide particles include spherical particles BL-200 (having a particle diameter of from 0.2 to 0.3 μm) and octahedral particles ABL-207A (having a particle diameter of 0.2 μm), each having been surface-coated with SiO₂.

Examples of the black complex metal oxides include complex metal oxides comprising at least two selected from Al, Ti, Cr, Mn, Fe, Co, Ni, Cu, Zn, Sb, and Ba. These can be prepared according to the methods disclosed in Japanese Patent O.P.I. Publication Nos. 9-27393, 9-25126, 9-237570, 9-241529 and 10-231441.

The complex metal oxide used in the invention is preferably a complex Cu—Cr—Mn type metal oxide or a Cu—Fe—Mn type metal oxide. The Cu—Cr—Mn type metal oxides are preferably subjected to the treatment disclosed in Japanese Patent O.P.I. Publication Nos. 8-27393 in order to reduce isolation of a 6-valent chromium ion. These complex metal oxides have a high color density and a high light-to-heat conversion efficiency as compared with another metal oxide.

The primary average particle diameter of these complex metal oxides is preferably not more than 1.0 μm, and more preferably from 0.01 to 0.5 μm. The primary average particle diameter of not more than 1.0 μm improves light-to-heat conversion efficiency relative to the addition amount of the particles, and the primary average particle diameter of from 0.01 to 0.5 μm further improves light-to-heat conversion efficiency relative to the addition amount of the particles.

The light-to-heat conversion efficiency relative to the addition amount of the particles depends on dispersity of the particles, and the well-dispersed particles have high light-to-heat conversion efficiency. Accordingly, these complex metal oxide particles are preferably dispersed according to a known dispersing method, separately to obtain a dispersion liquid (paste), before added to a coating liquid for the particle containing layer. A dispersant is optionally used for dispersion. The addition amount of the dispersant is preferably from 0.01 to 5% by weight, and more preferably from 0.1 to 2% by weight, based on the weight of the complex metal oxide particles.

In the invention, of these, a dye having less color is preferably used.

[Thermosensitive Image Formation Layer]

The printing plate material of the invention preferably comprises a thermosensitive image formation layer.

The thermosensitive image formation layer is a layer on which an image is formed on heating, and contains a heat melting material, a heat fusible material or a material (a hydrophobe precursor) which changes from hydrophilic to hydrophobic by heating. In the invention, the image formation layer is preferably a layer wherein an image is formed by heat generated due to infrared laser exposure.

As the hydrophobe precursor can be used a polymer whose property is capable of changing from a hydrophilic property (a water dissolving property or a water swelling property) or to a hydrophobic property by heating. Examples of the hydrophobe precursor include a polymer having an aryldiazosulfonate unit as disclosed in for example, Japanese Patent O.P.I. Publication No. 200-56449.

The heat melting material or heat fusible material used in the thermosensitive image formation layer is preferably in the form of particles. The particles of the heat melting material or heat fusible material are the same as those denoted in the particles described above to which the sensitizing dye is adhered.

[Other Compounds Optionally Contained in the Thermosensitive Image Formation Layer]

The image formation layer in the invention can further contain the following compounds.

The image formation layer in the invention can further contain the light-to-heat conversion material described above. The image formation layer in the invention preferably contains a material with a low color density.

The image formation layer can contain water soluble resins or water dispersible resins. Water soluble resins or water dispersible resins include oligosaccharides, polysaccharides, polyethylene oxide, polypropylene oxide, polyvinyl alcohol, polyethylene glycol (PEG), polyvinyl ether, a styrene-butadiene copolymer, a conjugation diene polymer latex of methyl methacrylate-butadiene copolymer, an acryl polymer latex, a vinyl polymer latex, polyacrylic acid, polyacrylic acid salts, polyacrylamide, and polyvinyl pyrrolidone. Among these, oligosaccharides, polysaccharides or polyacrylic acid, polyacrylic acid salts (sodium salt, etc.), and polyacrylamide are preferred. Examples of the oligosaccharides include raffinose, trehalose, maltose, galactose, sucrose, and lactose. Among these, trehalose is preferred. Examples of the polysaccharides include starches, celluloses, polyuronic acid and pullulan. Among these, cellulose derivatives such as a methyl cellulose salt, a carboxymethyl cellulose salt and a hydroxyethyl cellulose salt are preferred, and a sodium or ammonium salt of carboxymethyl cellulose is more preferred.

The molecular weight of polyacrylic acid, polyacrylic acid salts (sodium salt, etc.), and polyacrylamide has a molecular weight of preferably from 3,000 to 5,000,000, and more preferably from 5,000 to 1,000,000.

A water-soluble surfactant may be contained in the image formation layer in the invention. A silicon atom-containing surfactant and a fluorine atom-containing surfactant can be used. The silicon atom-containing surfactant is especially preferred in that it minimizes printing contamination. The content of the surfactant is preferably from 0.01 to 3.0% by weight, and more preferably from 0.03 to 1.0% by weight based on the total weight of the image formation layer (or the solid content of the coating liquid).

The image formation layer in the invention can contain an acid (phosphoric acid or acetic acid) or an alkali (sodium hydroxide, silicate, or phosphate) to adjust pH.

The coating amount of the image formation layer is from 0.01 to 10 g/m², preferably from 0.1 to 3 g/m², and more preferably from 0.2 to 2 g/m².

[Protective Layer]

A protective layer can be provided on the thermosensitive image formation layer.

As materials in the protective layer, the water soluble resin or the water dispersible resin described above can be preferably used. The protective layer in the invention may be a hydrophilic overcoat layer disclosed in Japanese Patent O.P.I. Publication Nos. 2002-19318 and 2002-86948.

The coating amount of the protective layer is from 0.01 to 10 g/m², preferably from 0.1 to 3 g/m², and more preferably from 0.2 to 2 g/m².

[Image Formation Method]

When a printing plate is prepared from the printing plate material of the invention, image formation can be carried out by heating, and preferably by exposure by infrared laser.

The planographic printing plate material of the invention is imagewise exposed to prepare a printing plate. The imagewise exposure is preferably scanning exposure, which is carried out employing a laser which can emit light having a wavelength of infrared and/or near-infrared regions, that is, a wavelength of from 700 to 1000 nm. As the laser, a gas laser can be used, but a semi-conductor laser, which emits light having a near-infrared region wavelength, is preferably used.

A device suitable for the scanning exposure in the invention may be any device capable of forming an image on the printing plate material according to image signals from a computer employing a semi-conductor laser.

Generally, the scanning exposures include the following processes.

(1) a process in which a plate material provided on a fixed horizontal plate is scanning exposed in two dimensions, employing one or several laser beams.

(2) a process in which the surface of a plate material provided along the inner peripheral wall of a fixed cylinder is subjected to scanning exposure in the rotational direction (in the main scanning direction) of the cylinder, employing one or several lasers located inside the cylinder, moving the lasers in the normal direction (in the sub-scanning direction) to the rotational direction of the cylinder.

(3) a process in which the surface of a plate material provided along the outer peripheral wall of a fixed cylinder is subjected to scanning exposure in the rotational direction (in the main scanning direction) of the cylinder, employing one or several lasers located inside the cylinder, moving the lasers in the normal direction (in the sub-scanning direction) to the rotational direction of the cylinder.

In the invention, the process (3) above is preferable, and especially preferable when a printing plate material mounted on a plate cylinder of a printing press is scanning exposed.

(On-Press Development)

In the invention, the image formation layer at portions exposed by for example, infrared laser form image portions laser, and the image formation layer at unexposed portions are removed to form non-image portions. Removal of the image formation layer can be carried out by washing with water, and can be also carried out by supplying dampening solution and/or printing ink to the image formation layer on a press (so-called on-press development).

Removal on a press of the image formation layer at non-image portions (unexposed portions) of a printing plate material, which is mounted on the plate cylinder, can be carried out by bringing a dampening roller and an inking roller into contact with the image formation layer while rotating the plate cylinder, and can be also carried out according to various sequences such as those described below or another appropriate sequence. The supplied amount of dampening solution may be adjusted to be greater or smaller than the amount ordinarily supplied in printing, and the adjustment may be carried out stepwise or continuously.

(1) A dampening roller is brought into contact with the image formation layer of a printing plate material on the plate cylinder during one to several tens of rotations of the plate cylinder, and then an inking roller brought into contact with the image formation layer during the next one to tens of rotations of the plate cylinder. Thereafter, printing is carried out.

(2) An inking roller is brought into contact with the image formation layer of a printing plate material on the plate cylinder during one to several tens of rotations of the plate cylinder, and then a dampening roller brought into contact with the image formation layer during the next one to tens of rotations of the plate cylinder. Thereafter, printing is carried out.

(3) An inking roller and a dampening roller are brought into contact with the image formation layer of a printing plate material on the plate cylinder during one to several tens of rotations of the plate cylinder. Thereafter, printing is carried out.

As a printing press, a conventional off-set printing press for a planographic printing plate is employed.

### EXAMPLES

The present invention will be explained below employing examples, but is not limited thereto. In the examples, “parts” is parts by weight, unless otherwise specified.

(Preparation of Support 1)

A 0.24 mm thick aluminum plate (1050, H16) was immersed in an aqueous 1% by weight sodium hydroxide solution at 50° C. to give an aluminum dissolution amount of 2 g/m², washed with water, immersed in an aqueous 0.1% by weight hydrochloric acid solution at 25° C. for 30 seconds to neutralize, and then washed with water.

Subsequently, the aluminum plate was subjected to an electrolytic surface-roughening treatment in an electrolytic solution containing 10 g/liter of hydrochloric acid and 0.5 g/liter of aluminum at a peak current density of 50 A/dm² employing an alternating current with a sine waveform, in which the distance between the plate surface and the electrode was 10 mm. The electrolytic surface-roughening treatment was divided into 12 treatments, in which the quantity of electricity used in one treatment (at a positive polarity) was 30 C/dm², and the total quantity of electricity used (at a positive polarity) was 360 C/dm². Standby time of 5 seconds, during which no surface-roughening treatment was carried out, was provided after each of the separate electrolytic surface-roughening treatments.

Subsequently, the resulting aluminum plate was immersed in an aqueous 1% by weight sodium hydroxide solution at 50° C. and etched to give an aluminum etching amount (including smut produced on the surface) of 1.2 g/m², washed with water, neutralized in an aqueous 10% by weight sulfuric acid solution at 25° C. for 10 seconds, and washed with water. Subsequently, the aluminum plate was subjected to anodizing treatment in an aqueous 20% by weight sulfuric acid solution at a constant voltage of 20 V, in which a quantity of electricity of 150 C/dm2 was supplied, and washed with water.

The washed surface of the plate was squeegeed, and the plate was immersed in an aqueous 0.5% by weight sodium silicate solution at 70° C. for 30 seconds, washed with water, and dried at 80° C. for 5 minutes. Thus, Support 1 was obtained.

The surface roughness Ra of the support 2 was 400 nm, measured by a factor of 40 employing “RST Plus” (produced by WYKO Co., Ltd.).

(Preparation of Support 2)

Both surfaces of a 175 μm thick biaxially stretched polyester sheet were corona discharged under condition of 8 W/m²·minute. Then, the surface on one side of the resulting sheet was coated with the following subbing layer coating solution (a) to give a first subbing layer with a dry thickness of 0.8 μm, and then coated with the following subbing layer coating solution (b) to give a second subbing layer with a dry thickness of 0.1 μm, while the first subbing layer was corona discharged under condition of 8 W/m ² minute, each layer was dried at 180° C. for 4 minutes (subbing layer A was formed).

Successively, the surface on the other side of the resulting sheet was coated with the following subbing layer coating solution (c) to give a third subbing layer with a dry thickness of 0.8 μm, and then coated with the following subbing layer coating solution (d) to give a fourth subbing layer with a dry thickness of 1.0 μm, while the third subbing layer was corona discharged under condition of 8 W/m² minute, each layer was dried at 180° C. for 4 minutes (subbing layer B was formed. Thus, support 1 having a subbing layer on each surface was prepared. Support 2 had a surface electric resistance at 25° C. and 25% RH of 10⁶ Ω.

| | |
|---|---|
| <<Subbing Layer Coating Solution (a)>> | |
| Latex of styrene/glycidyl methacrylate/butyl acrylate | 6.3 parts |
| (60/39/1) copolymer (Tg = 75° C.) | |
| Latex of styrene/glycidyl methacrylate/butyl acrylate | 1.6 parts |
| (20/40/40) copolymer | |
| (in terms of solid content) | |
| Anionic surfactant S-1 | 0.1 parts |
| Water | 92.0 parts |
| <<Subbing Layer Coating Solution (b)>> | |
| Gelatin | 1.0 parts |
| Anionic surfactant S-1 | 0.05 parts |
| Hardener H-1 | 0.02 parts |
| Matting agent (Silica particles | 0.02 parts |
| with an average particle diameter of 3.5 μu) | |
| Antifungal agent F-1 | 0.01 parts |
| Water | 98.9 parts |

| | |
|---|---|
| S-1 | 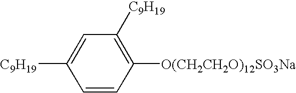 |
| H-1 | 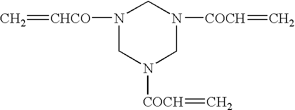 |
| F-1 | 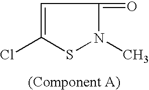 |
| | 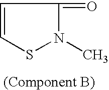 |
| | 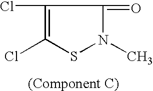 |

(Component A):(Component B):(Component C) = 50:46:4 (by mole)

| | |
|---|---|
| <<Subbing Layer Coating Solution (c)>> | |
| Latex of styrene/glycidyl methacrylate/butyl acrylate | 0.4 parts |
| (20/40/40) copolymer | |
| Latex of styrene/glycidyl methacrylate/butyl | 7.6 parts |
| acrylate/acetoacetoxyethyl methacrylate (39/40/20/1) | |
| copolymer | |
| Anionic surfactant S-1 | 0.1 parts |
| Water | 91.9 parts |
| <<Subbing Layer Coating Solution (d)>> | |
| Conduction composition of | 6.4 parts |
| *Component d-1/Component d-2/Component d-3 | |
| (=66/31/1) | |
| Hardener H-2 | 0.7 parts |
| Anion surfactant S-1 | 0.07 parts |
| Matting agent (Silica particles with | 0.03 parts |
| an average particle diameter of 3.5 μm) | |
| Water | 92.8 parts |
| *Component d-1 | |
| Copolymer of styrene sulfonic acid/maleic acid (50/50) | |
| *Component d-2 | |
| Latex of styrene/glycidyl methacrylate/butyl acrylate | |
| (20/40/40) copolymer | |
| *Component d-3 | |
| Copolymer of styrene/sodium isoprene sulfonate (80/20) | |
| (Polymer surfactant) | |
| H-2 | |
| Mixture of three compounds below | |
| 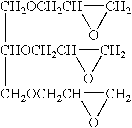 | |
| 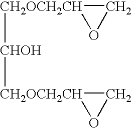 | |
| 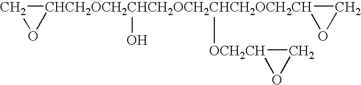 | |

### Example 1

Preparation of Dye Aqueous Dispersion 1

[Preparation of Dye Solution 1]

A 1% by weight ethanol solution of infrared absorbing dye, Exemplified dye IR-23 was prepared. The infrared absorbing dye IR-23 was added to ethanol at 25° C. with stirring, and subjected to ultrasonic treatment for 15 minutes to completely dissolve in the ethanol. Thus, dye solution 1 was obtained.

[Preparation of Aqueous Dispersion 1]

Materials shown in Table 1 below were mixed with stirring to obtain an aqueous dispersion 1.

TABLE 1
Composition of Aqueous Dispersion 1

| | |
|---|---|
| Carnauba wax emulsion A118 (the wax | 11.00 parts by weight |
| having an average particle diameter of | |
| 0.3 μm, a softening point of 65° C., a | |
| melting point of 80° C., a melt | |
| viscosity at 140° C. of 8 cps, and | |
| having a solid content of 40% by | |
| weight, produced by Gifu Shellac Co., | |
| Ltd.) | |
| Aqueous solution of sodium | 1.33 parts by weight |
| polyacrylate: AQUALIC DL522 (solid | |
| content 30%, produced by Nippon | |
| Shokubai Co., Ltd.) | |
| Pure water | 67.67 parts by weight |

Subsequently, 20 parts by weight of dye solution 1 was dropwise added to 80 parts by weight of aqueous dispersion 1 with stirring to obtain a dye aqueous dispersion 1 having a solid content of 5% by weight.

Dispersion of the resulting dye aqueous dispersion 1 was uniform, and there was no change in the dispersion state after it was allowed to stand for 5 hours.

The dye aqueous dispersion 1 was diluted to have a solid content of 0.5% by weight, and coated on a slide glass to form a thin layer so that each particle is not overlapped. The thin layer was observed at a magnification of 3000 by means of a microscope VH-7000, produced by KEYENCE CORPORATION, and it was found that the dye was located around the particles, showing that the dye was precipitated on the particles in the course of preparation of the dye aqueous dispersion 1.

Preparation of Dye Aqueous Dispersion 2

Dye aqueous Dispersion 2, having a solid content of 0.5% by weight, was prepared in the same manner as in Dye aqueous Dispersion 1 above, except that infrared absorbing dye, Exemplified dye IR-26 was used instead of Exemplified dye IR-23.

Dispersion of the resulting dye aqueous dispersion 2 was uniform, and there was no change in the dispersion state after it was allowed to stand for 5 hours.

The dye aqueous dispersion 2 was coated on a slide glass and observed by means of the microscope in the same manner as in the dye aqueous dispersion 1, and it was found that the dye was located around the particles.

Preparation of Dye Aqueous Dispersion 3 (Comparative)

Twenty parts by weight of the dye solution 1 obtained above was dropwise added to 67.67 parts by weight of pure water with stirring to obtain a mixture. When the stirring was stopped, it was observed that the dye precipitated in the mixture. Subsequently, 11 parts by weight of carnauba wax emulsion A118 and 1.33 parts by weight of sodium polyacrylate, AQUALIC DL522 were dropwise added in that order to the mixture with stirring. Thus, dye aqueous Dispersion 3, having a solid content of 5% by weight, was obtained.

After the dye aqueous dispersion 3 was allowed to stand for 5 hours, dye precipitation was observed in the dispersion.

The dye aqueous dispersion 3 was coated on a slide glass and observed by means of the microscope in the same manner as in the dye aqueous dispersion 1, and dyes having a particle size of several tens of micrometers were observed in the dispersion, but location of the dye around the particles was not.

Preparation of Water-Soluble Dye-Containing Aqueous Dispersion (Comparative)

A 1% by weight aqueous solution of an infrared absorbing dye (comparative) as shown below was prepared. The infrared absorbing dye was added to pure water at 25° C. with stirring, and subjected to ultrasonic treatment for 15 minutes to completely dissolve in water. Thus, a dye aqueous solution was obtained.
Infrared Absorbing Dye (Comparative)

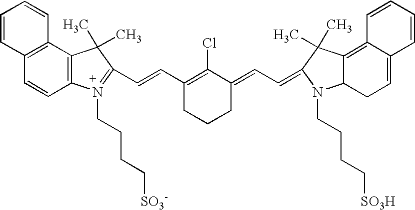

Subsequently, 20 parts by weight of the dye aqueous solution was dropwise added to 80 parts by weight of aqueous dispersion 1 (used in preparation of dye aqueous dispersion 1) with stirring to obtain a water-soluble dye-containing aqueous dispersion having a solid content of 5% by weight.

Dispersion of the resulting water-soluble dye-containing aqueous dispersion was uniform, and there was no change in the solution state of the dye or in the dispersion state after it was allowed to stand for 5 hours.

The water-soluble dye-containing aqueous dispersion was observed employing a microscope, and portions where particles did not exist were lightly colored, exhibiting presence of the dye.

Preparation of Alcohol-Soluble Dye-Containing Alcohol Dispersion (Comparative)

Twenty parts by weight of the dye solution 1 (used in preparation of dye aqueous dispersion 1) were diluted with 67.67 parts by weight of ethanol.

Eleven parts by weight of carnauba wax emulsion A118 and 1.33 parts by weight of sodium polyacrylate (AQUALIC DL522) were dropwise added in that order to the resulting diluted solution with stirring. Thus, a dye-containing alcohol dispersion having a solid content of 5% was obtained. This dispersion had a water content of less than 10% parts by weight, and there was no dye sedimentation in the dispersion.

The resulting dye-containing alcohol dispersion was observed employing a microscope, and portions where particles did not exist were lightly colored, exhibiting presence of the dye.

(Preparation of Printing Plate Material Sample)

[Printing Plate Material Sample 1]

The dye aqueous dispersion 1 (prepared in Example 1) was coated on the support 1 with a wire bar to form a light sensitive layer (thermosensitive image formation layer) with a dry coating amount of 0.8 g/m², dried at 55° C. for 3 minutes, and then subjected seasoning treatment at 40° C. for 24 hours. Thus, a printing plate material sample 1 was obtained.

[Printing Plate Material Sample 2]

Printing plate material sample 2 was prepared in the same manner as in printing plate material sample 1, except that the dye aqueous dispersion 2 was used instead of the dye aqueous dispersion 1.

[Printing Plate Material Sample 3]

Printing plate material sample 3 was prepared in the same manner as in printing plate material sample 1, except that the dye aqueous dispersion 3 was used instead of the dye aqueous dispersion 1.

[Printing Plate Material Sample 4]

Printing plate material sample 4 was prepared in the same manner as in printing plate material sample 1, except that the water-soluble dye-containing aqueous dispersion was used instead of the dye aqueous dispersion 1.

[Printing Plate Material Sample 5]

Printing plate material sample 5 was prepared in the same manner as in printing plate material sample 1, except that the water-soluble dye-containing aqueous dispersion was used instead of the dye aqueous dispersion 1.

(Filterability of Dampening Solution in Which Image Formation Layer is to be Dissolved Due to On-Press Development)

From the fact that the image formation layer is dissolved in a dampening solution due to on-press development of the exposed printing plate material sample, 100 g of each dispersion used for formation of the image formation layer of each printing plate material sample were added to 5 kg of a dampening solution to obtain a mixture solution.

As the dampening solution, a 2% by weight aqueous solution of Astromark 3 (produced by Nikken Kagaku Kenkyusyo Co., Ltd.) was used. All the mixture solutions exhibited coloration due to the dye used and turbidity due to particles dispersed in it.

Successively, the resulting mixture solutions were re-circulation-filtered employing a filter. As the filter, a Ultipleat Profile 045 (a cylindrical filter having a height of 1 inch), produced by PALL CORPORATION, was used, and the flow rate was 500 g/minute.

The re-circulation-filtration was carried out for 2 hours, coloration or turbidity of the mixture solutions was visually observed as a measure of filterability of a dampening solution. The results are shown in Table 2.

(Image Formation Employing Infrared Laser)

Each of the resulting printing plate samples was wound around an exposure drum and imagewise exposed. Exposure was carried out employing an infrared laser (having a wavelength of 830 nm and a beam spot diameter of 18 μm) at a resolution of 2400 dpi and at a screen line number of 175 to form a solid image, a dot image with an dot area of 1 to 99.%, and a line and space image of 2400 dpi. In the exposure, the exposure energy was varied from 150 to 500 mJ/cm² at an interval of 50 mJ/cm². The term, “dpi” shows the number of dots per 2.54 cm.

(Printing Method)

Printing was carried out employing a printing press, DAIYA 1F-1 produced by Mitsubishi Jukogyo Co., Ltd., and employing a coated paper, a dampening solution, a 2% by weight solution of Astromark 3 (produced by Nikken Kagaku Kenkyusyo Co., Ltd.), and printing ink (Toyo King Hyecho M Magenta, produced by Toyo Ink Manufacturing Co.). Printing was carried out in the same printing sequence as a conventional PS plate.

(Evaluation)

[Initial Printability]

Employing a printing plate material sample exposed at appropriate exposure energy, the number of paper sheets printed from when printing started till when good image (with a solid image with a density of 1.5 or more and without stain) was obtained was counted and evaluated as a measure of initial printability. The results are shown in Table 2. However, when one hundredth print did not give the good image, the number was evaluated as >100, and its reason (for example, stain occurrence at non-image portions or insufficient image formation) was added.

[Sensitivity]

Printing was carried out to obtain 1000 copies. The lowest exposure energy (mJ/cm²) at which an image with a 2% dot area is reproduced in the 1000^{th} copy was defined as sensitivity. The results are shown in Table 2. When sensitivity was determined, the image and stain occurrence at non-image portions was separately observed.

As is apparent from Table 2, inventive printing plate material samples exhibits excellent sensitivity and initial printability. Further, when the inventive samples are employed, materials constituting the image formation layer incorporated into a dampening solution on on-press development can be filtered off by filtration, and there is, therefore, no problem of contamination of the dampening solution.

TABLE 2

| Printing | Filterability of | | | | |
|---|---|---|---|---|---|
| Plate | Dampening Solution | | | | |
| Material | | Turbidity | Initial | | |
| Sample | Coloration | due to | Printability | Sensitivity | |
| No. | due to Dye | Particles | (number) | (mJ/cm²) | Remarks |
| 1 | No | No | 10 | 250 | Inv. |
| 2 | No | No | 10 | 200 | Inv. |
| 3 | No | No | >100 | >500 | Comp. |
| | | | Insufficient | | |
| | | | Image | | |
| | | | Formation | | |
| 4 | Yes | No | 10 | 300 | Comp. |
| 5 | No | No | >100 | 250 | Comp. |
| | | | Stain | | |
| | | | Occurrence | | |

Inv.: Inventive,
Comp.: Comparative

### Example 2

[Preparation of Printing Plate Material Sample 6]

Materials as shown in Table 3 were sufficiently mixed while stirring at 3000 rpm for 5 minutes, employing a homogenizer, and filtered to obtain a lower hydrophilic layer coating solution with a solid content of 30% by weight.

The lower hydrophilic layer coating solution was coated on the surface of the subbing layer A side of support 2 with a wire bar to obtain a lower hydrophilic layer with a dry thickness of 3.5 g/m², and dried at 100° C. for 3 minutes.

TABLE 3
Composition of Lower Hydrophilic Layer Coating Solution

| | |
|---|---|
| Black iron oxide particles ABL-207 | 13.50 parts by weight |
| (produced by Titan Kogyo K.K., | |
| octahedral form, average particle | |
| diameter: 0.2 μm, acicular ratio: | |
| substantially 1, specific surface | |
| area: 6.7 m²/g, Hc: 9.95 kA/m, σs: | |
| 85.7 Am²/kg, σr/σs: 0.112) | |
| Porous metal oxide particles JC70 | 3.00 parts by weight |
| (Porous aluminosilicate particles, | |
| average particle diameter: 7 μm, | |
| produced by Mizusawa | |
| Kagaku Co., Ltd.) | |
| Colloidal silica (alkali type): | 63.75 parts by weight |
| Snowtex XS (solid content: 20% by | |
| weight, produced by Nissan Kagaku | |
| Co., Ltd.) | |
| Chitosan particle dispersion (produced | 10.00 parts by weight |
| by Dainichi Seika Co., Ltd., a | |
| deacetylation degree of 90% or more, | |
| average particle diameter: 2 μm, solid | |
| content: 6% by weight | |
| Aqueous 10% by weight sodium | 1.50 parts by weight |
| phosphate.dodecahydrate solution | |
| (Reagent produced by Kanto Kagaku | |
| Co., Ltd.) | |
| Pure water | 8.25 parts by weight |

Materials as shown in Table 4 were sufficiently mixed while stirring at 10,000 rpm for 10 minutes, employing a homogenizer, and filtered to obtain a hydrophilic layer 1 coating solution with a solid content of 10% by weight.

Subsequently, the hydrophilic layer 1 coating solution was coated on the resulting lower hydrophilic layer with a wire bar to obtain an image formation layer 1 with a dry coating amount of 0.7 g/m², dried at 100° C. for 3 minutes, and then subjected to seasoning treatment at 60° C. for 24 hours.

TABLE 4
Composition of Hydrophilic Layer 1 Coating Solution

| | |
|---|---|
| Cu—Fe—Mn type metal oxide black | 5.00 parts by weight |
| pigment: TM-3550 black aqueous | |
| dispersion {prepared by dispersing TM- | |
| 3550 black powder having a particle | |
| diameter of 0.1 μm produced by | |
| Dainichi Seika Kogyo Co., Ltd. in | |
| water to give a solid content of 40% | |
| by weight (including 0.2% by weight of | |
| dispersant)} | |
| Colloidal silica (alkali type): | 8.87 parts by weight |
| Snowtex S (solid 30% by weight, | |
| produced by Nissan Kagaku Co., Ltd.) | |
| Necklace shaped colloidal silica | 19.95 parts by weight |
| (alkali type): Snowtex PSM (solid 20% | |
| by weight, produced by Nissan Kagaku | |
| Co., Ltd.) | |
| Porous metal oxide particles Silton | 1.00 parts by weight |
| AMT08 (porous aluminosilicate | |
| particles having an average particle | |
| diameter of 0.6 μm, produced by | |
| Mizusawa Kagaku Co., Ltd.) | |
| Layer structural clay mineral | 4.00 parts by weight |
| particles: Montmorillonite Mineral | |
| Colloid MO gel prepared by vigorously | |
| stirring montmorillonite Mineral | |
| Colloid MO; gel produced by Southern | |
| Clay Products Co., Ltd. (average | |
| particle diameter: 0.1 μm) in water in | |
| a homogenizer to give a solid content | |
| of 5% by weight | |
| Aqueous 4% by weight sodium | 2.50 parts by weight |
| carboxymethyl cellulose solution | |
| (Reagent produced by Kanto Kagaku | |
| Co., Ltd.) | |
| Aqueous 10% by weight sodium | 0.50 parts by weight |
| phosphate.dodecahydrate solution | |
| (Reagent produced by Kanto Kagaku | |
| Co., Ltd. | |
| Pure water | 58.18 parts by weight |

Subsequently, dye aqueous dispersion 1 prepared in Example 1 was coated on the hydrophilic layer 1 to form an image formation layer with a dry thickness of 0.6 g/m², and dried at 55° C. for 3 minutes, and further subjected to seasoning treatment at 55° C. for 24 hours. Thus, a printing plate material sample 6 was prepared.

[Preparation of Printing Plate Material Sample 7]

Printing plate material sample 7 was prepared in the same manner as in printing plate material sample 6 above, except that dye aqueous dispersion 2 prepared in Example 1 was used instead of dye aqueous dispersion 1.

[Preparation of Printing Plate Material Sample 8]

Materials as shown in Table 5 below were sufficiently mixed while stirring at 3000 rpm for 5 minutes, employing a homogenizer, and filtered to obtain a hydrophilic layer 2 coating solution with a solid content of 30% by weight. The hydrophilic layer 2 coating solution was coated on the surface of the subbing layer A side of support 2 with a wire bar to obtain a hydrophilic layer 2 with a dry thickness of 4.0 g/m², and dried at 100° C. for 3 minutes.

TABLE 5
Composition of Hydrophilic Layer 2 Coating Solution

| | |
|---|---|
| Black iron oxide particles ABL-207 | 13.50 parts by weight |
| (produced by Titan Kogyo K.K., | |
| octahedral form, average particle | |
| diameter: 0.2 μm, acicular ratio: | |
| substantially 1, specific surface | |
| area: 6.7 m²/g, Hc: 9.95 kA/m, σs: | |
| 85.7 Am²/kg, σr/σs: 0.112) | |
| Porous metal oxide particles JC50 | 1.50 parts by weight |
| (Porous aluminosilicate particles, | |
| average particle diameter: 5 μm, | |
| produced by Mizusawa Kagaku | |
| Co., Ltd.) | |
| Colloidal silica (alkali type): | 71.25 parts by weight |
| Snowtex XS (solid content: 20% by | |
| weight, produced by Nissan Kagaku | |
| Co., Ltd.) | |
| Chitosan particle dispersion (produced | 10.00 parts by weight |
| by Dainichi Seika Co., Ltd., a | |
| deacetylation degree of 90% or more, | |
| average particle diameter: 2 μm, solid | |
| content: 6% by weight | |
| Aqueous 10% by weight sodium | 1.50 parts by weight |
| phosphate.dodecahydrate solution | |
| (Reagent produced by Kanto Kagaku | |
| Co., Ltd.) | |
| Pure water | 8.25 parts by weight |

Subsequently, dye aqueous dispersion 2 prepared in Example 1 was coated on the hydrophilic layer 2 to form an image formation layer with a dry thickness of 0.6 g/m², and dried at 55° C. for 3 minutes, and further subjected to seasoning treatment at 55° C. for 24 hours. Thus, a printing plate material sample 8 was prepared.

[Preparation of Printing Plate Material Sample 9]

Printing plate material sample 7 was prepared in the same manner as in printing plate material sample 6 above, except that the water-soluble dye-containing aqueous dispersion prepared in Example 1 was used instead of the dye aqueous dispersion 1.

(Image Formation Employing Infrared Laser)

Each of the resulting printing plate samples was wound around an exposure drum and imagewise exposed. Exposure was carried out in the same manner as in Example 1, except that exposure energies of 120 mJ/cm², 150 mJ/cm², and 200 mJ/cm² were employed.

(Printing Method)

Printing was carried out in the same manner as in Example 1 to obtain 20,000 copies, except that woodfree paper was used as a printing paper.

(Evaluation)

[Printing Durability]

Printing durability was evaluated based on image quality of 3% dot image of prints at each of the exposure energies. The number of paper sheets printed from when printing started till when missing of 3% dot image was observed was counted and evaluated as a measure of printing durability. The results are shown in Table 6.

TABLE 6

| Printing | | | | |
|---|---|---|---|---|
| Plate | Printing Durability at Each Exposure | | | |
| Material | Energy (number) | | | |
| Sample No. | 120 mJ/cm² | 150 mJ/cm² | 200 mJ/cm² | Remarks |
| 6 | >20,000 | >20,000 | >20,000 | Inventive |
| 7 | >20,000 | >20,000 | >20,000 | Inventive |
| 8 | >20,000 | >20,000 | >20,000 | Inventive |
| 9 | 4,000 | 9,000 | 15,000 | Comparative |

As is apparent from Table 6, inventive printing plate material samples exhibits excellent on-press developability, and good printing durability even at lower exposure energy as well as excellent sensitivity and printing durability.

### EFFECTS OF THE INVENTION

The present invention can provide a printing plate material providing high sensitivity, excellent on-press developability, and high printing durability.

1. A printing plate material comprising a support and provided thereon, a light sensitive layer containing a sensitizing dye, which is insoluble in water and soluble in an organic solvent, and particles to which the sensitizing dye is adhered.

2. The printing plate material of claim 1, wherein the sensitizing dye absorbs a light having a wavelength of from 700 to 1300 μm.

3. The printing plate material of claim 1, further comprising a thermosensitive image formation layer provided on the support.

4. The printing plate material of claim 3, wherein the thermosensitive image formation layer, after imagewise exposure, is capable of being developed with a dampening solution or a printing ink on printing.

5. The printing plate material of claim 1, wherein the light sensitive layer is a thermosensitive image formation layer.

6. The printing plate material of claim 1, wherein the particles are resin particles or microcapsules whose walls consist of a resin.

7. The printing plate material of claim 6, wherein the resin particles are heat melting particles or heat fusible particles.

8. The printing plate material of claim 1, wherein the light sensitive layer further contains a sensitizing dye in the form of particles.

9. A process of manufacturing a printing plate material comprising a support and provided thereon, a light sensitive layer containing a sensitizing dye, which is insoluble in water and soluble in an organic solvent, and particles to which the sensitizing dye is adhered, the process comprising the steps of:
mixing an aqueous dispersion of particles with an organic solvent solution of a sensitizing dye to obtain a light sensitive layer coating liquid; and
coating the light sensitive layer coating liquid on the support.

10. The process of claim 9, wherein the organic solvent is miscible in water.

11. The process of claim 10, wherein the organic solvent is alcohol.

12. The process of claim 9, wherein the light sensitive layer coating liquid contains water in an amount of not less than 10% by weight.
